(19) United States
(12) Patent Application Publication
(10) Pub. No.: US 2005/0161696 A1
(43) Pub. Date: Jul. 28, 2005

(54) Semiconductor light-emitting device and method for fabricating the same

(75) Inventor: Masaaki Yuri, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/037,188

(22) Filed: Jan. 19, 2005

(30) Foreign Application Priority Data
Jan. 28, 2004 (JP) 2004-019410

(51) Int. Cl. H01L 33/00; H01L 21/00

(52) U.S. Cl. 257/103; 438/22

(57) ABSTRACT

In a semiconductor light-emitting device formed by stacking a plurality of semiconductor layers including an active layer, at least a portion of a semiconductor layer of the plurality of semiconductor layers is made porous. The semiconductor layer made porous has a surface serving as a light-extraction surface for extracting light emitted from the active layer.

### CROSS-REFERENCE TO RELATED APPLICATIONS

This application claims priority under 35 U.S.C. § 119 on Patent Application No. 2004-019410 filed in Japan on Jan. 28, 2004, the entire contents of which are hereby incorporated by reference.

### BACKGROUND OF THE INVENTION

(a) Fields of the Invention

The present invention relates to semiconductor light-emitting devices, typified by light-emitting diodes (referred hereinafter to as LEDs), usable as various types of indicators, backlights for liquid-crystal displays, light sources for solid illuminations, and the like.

(b) Description of Related Art

In recent years, LEDs have been growingly sophisticated in functionality and application areas of the LEDs have been increasingly widened rapidly. In particular, with the advent of nitride-based compound semiconductors typified by gallium nitride (referred hereinafter to as GaN), LEDs covering a wide range from ultraviolet to all visible regions have come to be realized. Thus, the LEDs are now a focus of attention not only as simple indication lights but also as light sources for illuminations as an alternative to fluorescent lamps and incandescent lamps.

One of big issues for recent LEDs is to improve the light-extraction efficiency thereof. The reason for this is as follows. A simple LED chip is fabricated in such a manner that a substrate of a semiconductor wafer with multilayer structures formed on the surface thereof is split by dicing into chip forms in substantially rectangular parallelepipeds. In the simple LED chip thus fabricated, most part of light emitted from an active layer of the chip is totally reflected at the interface between semiconductor and air or resin, and then confined in the LED chip. Therefore, only an extremely small part of light can be extracted from the chip. In such a simple LED structure, generally, the light-extraction efficiency, that is, the rate of possible extraction of light produced in the active layer to the outside of the LED chip is estimated at about 20% only.

To resolve this issue, various approaches are taken in which a light-extraction surface of an LED is textured to increase the light-extraction efficiency. Examples of the surface texturing of the light-extraction surface include a surface texturing as described in Japanese Unexamined Patent Publication No. 2000-196152, or a surface texturing described by Orita and et al., “Enhanced Light Extraction Efficiency of GaN-based Blue LED Using Extended-Pitch Surface Photonic Crystal” Digest of 2003 (H15) Autumn JSAP annual meeting, Vol. 3, pp. 938 (published on Aug. 30, 2003 by The Japan Society of Applied Physics).

FIG. 14 shows the cross-sectional structure of a conventional LED of which a light-extraction surface is textured to improve the light-extraction efficiency. Referring to FIG. 14, on top of a sapphire substrate 101, an n-type GaN layer 102, an InGaN multiple quantum well active layer 103, a p-type AlGaN barrier layer 104, and a p-type GaN contact layer 105 are sequentially stacked. In this structure, the surface of the p-type GaN contact layer 105 is provided with regular projections and depressions made by lithography and dry etching techniques. On top of the p-type GaN contact layer 105, a p-side ohmic electrode 106 is provided with a transparent electrode 107 interposed therebetween. Note that of the stack structure of the semiconductor layers shown above, an n-side ohmic electrode formation region is removed by etching to expose the n-type GaN layer 102, and an n-side ohmic electrode 108 is formed on the exposed surface of the n-type GaN layer 102.

The conventional LED shown in FIG. 14 can prevent light emitted from the active layer 103 from being totally reflected at the surface of the GaN contact layer 105 serving as the light-extraction surface, and thereby can enhance the light-extraction efficiency by about double.

### SUMMARY OF THE INVENTION

However, in the conventional technique described above, the light-extraction surface is formed with the regular projections and depressions, which causes a practical problem that a radiation pattern of light radiated from the LED chip is strengthened in specific directions by interference between diffracted lights. Further, since dry etching is used to form the projections and depressions in the p-type GaN layer serving as the light-extraction surface, the p-type GaN layer is damaged. This causes a problem that an ohmic electrode is difficult to form on the p-type GaN layer and a problem that light is absorbed into deep levels created in the p-type GaN layer.

Moreover, if light emitted from the active layer has a short wavelength, light absorption into the p-type GaN layer cannot be ignored. Therefore, the need arises to form the layer serving as the light-extraction surface of a material having a larger band gap energy than GaN, such as AlGaN. However, if the conventional technique described above is employed in this case, the following problems arise. First, since materials having large band gap energies generally have strong bonds and are firm, such materials are difficult to etch to form projections and depressions. Second, on a layer made of the material having a large bad gap energy, formation of an ohmic electrode is further difficult.

Furthermore, in the conventional technique described above, fine lithography technique has to be used to form small-pitched projections and depressions in the light-extraction surface. This causes a problem of a decrease in the yield of the chip.

With the foregoing in mind, an object of the present invention is to provide a semiconductor light-emitting device having a high light-extraction efficiency and a good radiation pattern without employing fine lithography technique and dry etching technique.

To accomplish the above object, in a semiconductor light-emitting device according to the present invention formed by stacking a plurality of semiconductor layers including an active layer, at least a portion of a semiconductor layer of the plurality of semiconductor layers is made porous, the semiconductor layer having a surface serving as a light-extraction surface for extracting light emitted from the active layer.

In the description of the present invention, the wording “made porous” means that in the portion made porous, that is, in the porous portion, a great number of fine voids (air gaps) with various shapes are present randomly.

With the semiconductor light-emitting device of the present invention, a large number of air gaps are randomly formed in the semiconductor layer having the surface serving as the light-extraction surface. This prevents light emitted from the active layer from being totally reflected at the surface of the semiconductor layer serving as the light-extraction surface, whereby the light-extraction efficiency of the device can be improved. Moreover, the layer is made porous to form a great number of air gaps randomly. This avoids a situation where a specific radiation pattern of light radiated from the device is generated by interference between diffracted lights. Consequently, the semiconductor light-emitting device having a high light-extraction efficiency and a good radiation pattern can be provided.

Furthermore, with the semiconductor light-emitting device of the present invention, the semiconductor layer having the surface serving as the light-extraction surface can be made porous by wet etching. This avoids a problem that dry etching induces damages to the semiconductor layer.

Moreover, with the semiconductor light-emitting device of the present invention, the wavelength of the optical absorption edge (the wavelength at which the absorption coefficient of light sharply falls) of the semiconductor layer made porous shifts to shorter wavelength than that before the semiconductor layer is made porous. This reduces absorption of light emitted from the active layer, whereby the light-extraction efficiency of the device can be further improved.

Furthermore, in fabricating the semiconductor light-emitting device of the present invention, it is unnecessary to use a sophisticated photolithography technique. This enhances the fabrication yield.

Preferably, in the semiconductor light-emitting device of the present invention, air gaps in the porous region of the semiconductor layer have irregularities in their bottom levels. More preferably, in this device, the difference in level of the irregularities is about 10 nm or greater.

With this device, by the porous region of the semiconductor layer, light emitted from the active layer can be scattered more effectively. Therefore, a good radiation pattern without any specific interference peaks is attained and concurrently the light power of the device can be enhanced.

Preferably, in the semiconductor light-emitting device of the present invention, the porous region of the semiconductor layer has a plurality of remaining semiconductor portions whose tops form irregularities as a whole. More preferably, in this device, the difference in level of the irregularities is about 10 nm or greater.

With this device, by the porous region of the semiconductor layer, light emitted from the active layer can be scattered more effectively. Therefore, a good radiation pattern without any specific interference peaks is attained and concurrently the light power of the device can be enhanced.

Preferably, in the semiconductor light-emitting device of the present invention, the plurality of semiconductor layers include another semiconductor layer not made porous, provided between the active layer and the semiconductor layer, and serving as a current diffusion layer, and an electrode is provided on a non-porous region of the semiconductor layer. More preferably, the current diffusion layer has at least one heterointerface.

With this device, another said semiconductor layer, that is, the current diffusion layer can promote lateral diffusion of carriers that hardly diffuse laterally in the semiconductor layer due to the presence of the porous structure. Therefore, a more uniform light emission can be provided from the entire surface of the light emission surface.

In the semiconductor light-emitting device of the present invention, if the distance between adjacent ones of the air gaps in the porous region of the semiconductor layer is 20 nm or smaller, an optical absorption edge of the porous region of the semiconductor layer has a shorter wavelength than that of the non-porous region of the semiconductor layer by the quantum effect. In this device, if the wavelength (center wavelength) of light emitted from the active layer is almost the same as the wavelength of the forbidden band of the semiconductor layer or shorter than that wavelength, the wavelength of the optical absorption edge of the porous region of the semiconductor layer is shorter than the center wavelength of light emitted from the active layer. Thus, the light emitted from the active layer can be extracted without any absorption into the semiconductor layer, so that the light-extraction efficiency of the device can be further improved.

Preferably, in the semiconductor light-emitting device of the present invention, the effective refractive index of the porous region of the semiconductor layer decreases as the distance from the active layer is increased.

With this device, the light-extraction efficiency of the device can be further improved. Note that “the effective refractive index of the porous region of the semiconductor layer” means the refractive index averaging the refractive index of the semiconductor portion and the refractive index of the air gap portion in consideration of the volume ratio between these portions.

Preferably, in the semiconductor light-emitting device of the present invention, the ratio of air gaps per unit volume of the porous region of the semiconductor layer rises as the distance from the active layer is increased.

With this device, the effective refractive index of the porous region of the semiconductor layer gradually decreases as the distance from the active layer is increased (that is, gradually decreases from the substrate side toward the surface side). Therefore, the light-extraction efficiency of the device can be further improved.

Preferably, in the semiconductor light-emitting device of the present invention, the band gap energy of the semiconductor layer stepwise or continuously decreases as the distance from the active layer is increased.

With this device, the ratio of air gaps per unit volume of the porous region of the semiconductor layer can be raised as the distance from the active layer is increased. As a consequence of this, the effective refractive index of the porous region of the semiconductor layer gradually decreases from the substrate side toward the surface side, so that the light-extraction efficiency of the device can be further improved.

Preferably, in the semiconductor light-emitting device of the present invention, portions of the semiconductor surface contacting with the air gaps in the porous region of the semiconductor layer are oxidized.

With this device, the semiconductor surface in the porous region is prevented from being directly exposed to an atmosphere, so that the reliability of the device is greatly improved.

Preferably, in the semiconductor light-emitting device of the present invention, the surface side of the porous region of the semiconductor layer is covered with a protection film.

With this device, the semiconductor surface in the porous region is prevented from being directly exposed to an atmosphere, so that the reliability of the device is greatly improved. In this case, as the protection film, use can be made of, for example, a film of SiO₂, Al₂O₃, SiN, TiO₂, ZrO₂, Nb₂O₅, Ta₂O₅, or Ga₂O₃.

Preferably, in the semiconductor light-emitting device of the present invention, the surface side of the porous region of the semiconductor layer is covered with a transparent electrode.

With this device, the semiconductor surface in the porous region is prevented from being directly exposed to an atmosphere, so that the reliability of the device is greatly improved. In addition, a more uniform carrier injection can be performed, so that the efficiency of light emission of the device can be still further improved.

Preferably, in the semiconductor light-emitting device of the present invention, the semiconductor layer is an n-type semiconductor layer.

With this device, a p-side electrode generally having a higher contact resistance than an n-side electrode can be formed on the entire surface of a p-type semiconductor layer of the plurality of semiconductor layers, which is the opposite surface to the light-extraction surface. This reduces the operating voltage of the device.

Preferably, in the semiconductor light-emitting device of the present invention, the plurality of semiconductor layers are formed on a substrate, and a reflection film made of metal or a multilayer dielectric structure is formed on one of principal surfaces of the substrate on which the plurality of semiconductor layers are not formed.

With this device, light emitted from the active layer toward the substrate is efficiently reflected by the formed reflection film, so that the efficiency of light extraction from the light-extraction surface can be further improved.

Preferably, in the semiconductor light-emitting device of the present invention, a reflection film made of metal or a multilayer dielectric structure is formed on a surface of a still another semiconductor layer of the plurality of semiconductor layers, the surface of the still another semiconductor layer being the opposite surface to the light-extraction surface.

With this device, light emitted from the active layer toward the still another semiconductor layer is efficiently reflected by the formed reflection film, so that the efficiency of light extraction from the light-extraction surface can be further improved.

In the semiconductor light-emitting device of the present invention, as a material for the plurality of semiconductor layers, use may be made of, for example, nitride-based compound semiconductor represented by BₓAl_{y}In_{z}Ga_{1-x-y-z}N (0≦x≦1, 0≦y≦1, 0≦z≦1, 0≦x+y+z≦1).

In the semiconductor light-emitting device of the present invention, if the wavelength of light emitted from the active layer is less than 430 nm, a white color LED can be fabricated.

In the semiconductor light-emitting device of the present invention, as a material for the semiconductor layer, use may be made of, for example, nitride-based compound semiconductor represented by AlₓGa₁₋ₓN (0≦x≦1).

A method for fabricating a semiconductor light-emitting device according to the present invention comprises the steps of sequentially forming, on a substrate, at least an n-type semiconductor layer, a semiconductor layer serving as an active layer, and a p-type semiconductor layer; separating a multilayer structure including the semiconductor layers from the substrate; and making at least a portion of the n-type semiconductor layer of the multilayer structure porous, the n-type semiconductor layer having a surface serving as a light-extraction surface for extracting light emitted from the active layer.

With the method for fabricating a semiconductor light-emitting device according to the present invention, the semiconductor layer having the surface serving as the light-extraction surface is made porous. This prevents light emitted from the active layer from being totally reflected at the surface of the semiconductor layer serving as the light-extraction surface, whereby the light-extraction efficiency of the device can be improved. Moreover, the layer is made porous to form a great number of air gaps randomly. This avoids a situation where a specific radiation pattern of light radiated from the device is generated by interference between diffracted lights. Consequently, the semiconductor light-emitting device having a high light-extraction efficiency and a good radiation pattern can be provided.

With the method for fabricating a semiconductor light-emitting device according to the present invention, the semiconductor layer having the surface serving as the light-extraction surface can be made porous by wet etching. This avoids a problem that dry etching induces damages to the semiconductor layer.

With the method for fabricating a semiconductor light-emitting device according to the present invention, the wavelength of the optical absorption edge of the semiconductor layer made porous shifts to shorter wavelength than that before the semiconductor layer is made porous. This reduces absorption of light emitted from the active layer, whereby the light-extraction efficiency of the device can be further improved.

With the method for fabricating a semiconductor light-emitting device according to the present invention, it is unnecessary to use a sophisticated photolithography technique. This enhances the fabrication yield.

With the method for fabricating a semiconductor light-emitting device according to the present invention, a p-side electrode generally having a higher contact resistance than an n-side electrode can be formed on the entire surface of a p-type semiconductor layer of the semiconductor multilayer structure, which is the opposite surface to the light-extraction surface. This reduces the operating voltage of the device.

As is apparent from the above, with the present invention, the semiconductor layer having the surface serving as the light-extraction surface is made porous, whereby air gaps are formed randomly in the semiconductor layer. This improves the light-extraction efficiency of the device without generating any specific radiation pattern resulting from interference between diffracted lights. Moreover, the semiconductor layer can be made porous by wet etching. This eliminates a problem of damages induced by dry etching. Furthermore, the wavelength of the optical absorption edge of the semiconductor layer made porous shifts to shorter wavelength than that before the semiconductor layer is made porous. This reduces absorption of light emitted from the active layer, whereby the light-extraction efficiency of the device can be further improved. Moreover, it is unnecessary to use a fine photolithography technique for fabrication of the device. This enhances the fabrication yield.

Accordingly, the semiconductor light-emitting device of the present invention is usable not only as simple indication lights but also as light sources for illuminations as an alternative to fluorescent lamps or incandescent lamps.

### BRIEF DESCRIPTION OF THE DRAWINGS

FIG. 1A is a plan view of a semiconductor light-emitting device according to a first embodiment of the present invention, and FIG. 1B is a sectional view taken along the line I-I in FIG. 1A.

FIG. 2 is a graph showing the current-light power characteristics of the semiconductor light-emitting device according to the first embodiment of the present invention.

FIG. 3 is a graph showing a radiation pattern of light radiated from the semiconductor light-emitting device according to the first embodiment of the present invention.

FIG. 4 is a view schematically showing the cross-sectional structure of a porous region of a contact layer in the semiconductor light-emitting device according to the first embodiment of the present invention.

FIG. 5 is a graph showing optical absorption spectra of the p-type GaN contact layer in the semiconductor light-emitting device according to the first embodiment of the present invention. In FIG. 5, the curve (a) shows the optical absorption spectrum of the porous region of the p-type GaN contact layer, and the curve (b) shows the optical absorption spectrum of a non-porous region of the p-type GaN contact layer.

FIG. 6 is a view schematically showing the cross-sectional structure of a porous region of a contact layer in the semiconductor light-emitting device according to a modification of the first embodiment of the present invention.

FIG. 7 is a sectional view of a semiconductor light-emitting device according to a second embodiment of the present invention.

FIG. 8 is a view schematically showing the cross-sectional structure of a porous region of a contact layer in the semiconductor light-emitting device of the second embodiment of the present invention.

FIG. 9 is a view schematically showing the cross-sectional structure of a porous region of a contact layer in a semiconductor light-emitting device according to a third embodiment of the present invention.

FIG. 10 is a view schematically showing the cross-sectional structure of a porous region of a contact layer in a semiconductor light-emitting device according to a fourth embodiment of the present invention.

FIG. 11 is a view schematically showing the cross-sectional structure of a porous region of a contact layer in a semiconductor light-emitting device according to a fifth embodiment of the present invention.

FIG. 12 is a sectional view of a semiconductor light-emitting device according to a sixth embodiment of the present invention.

FIG. 13 is a sectional view of a semiconductor light-emitting device according to a seventh embodiment of the present invention.

FIG. 14 is a sectional view of a conventional semiconductor light-emitting device.

### DETAILED DESCRIPTION OF THE PREFERRED EMBODIMENTS

### First Embodiment

Hereinafter, a semiconductor light-emitting device and a method for fabricating the device according to a first embodiment of the present invention will be described with reference to the accompanying drawings.

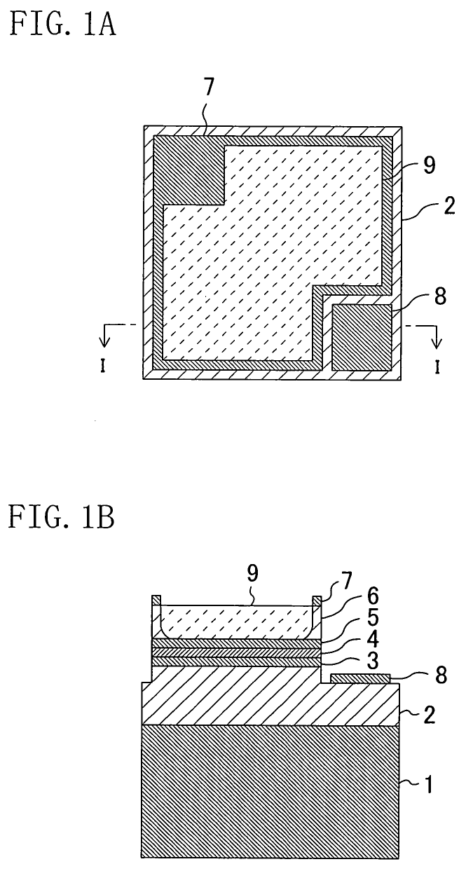

FIGS. 1A and 1B are views showing the structure of the semiconductor light-emitting device according to the first embodiment. FIG. 1A is a plan view thereof, and FIG. 1B is a sectional view taken along the line I-I in FIG. 1A.

The method for fabricating a semiconductor light-emitting device according to the first embodiment is as follows. As shown in FIGS. 1A and 1B, first, using a metal organic chemical vapor deposition method (referred hereinafter to as an MOCVD method) or the like, an n-type GaN layer 2 (about 3.0 μm thick), an InGaN multiple quantum well active layer 3, a p-type Al_{00.15}Ga_{0.85}N electron barrier layer 4 (10 nm thick), a p-type AlGaN/GaN strained superlattice layer 5, and a p-type GaN contact layer 6 (50 nm thick) are sequentially stacked on top of a sapphire substrate 1 of a wafer. In this structure, the InGaN multiple quantum well active layer 3 is formed by laminating three cycles of stacked structures each made of an In_{0.1}Ga_{0.9}N quantum well layer (2.5 nm thick) and an In_{0.02}Ga_{0.98}N barrier layer (5 nm thick). The p-type AlGaN/GaN strained superlattice layer 5 is formed by laminating fifty cycles of stacked structures each made of a p-type Al_{0.1}Ga_{0.9}N layer (1.5 nm thick) and a p-type GaN layer (1.5 nm thick).

Next, a p-side ohmic electrode 7 is formed to have an opening over a light extraction portion of the p-type GaN contact layer 6. Thereafter, the wafer on which the semiconductor layers shown above are stacked is immersed in, for example, a mixed solution of methanol, hydrofluoric acid, and hydrogen peroxide solution, thereby forming a porous structure (a porous region) 9 in the light extraction portion of the p-type GaN contact layer 6. Subsequently, of the stacked structure of the semiconductor layers shown above, an n-side ohmic electrode formation region is etched by dry etching to expose the n-type GaN layer 2, and then an n-side ohmic electrode 8 is formed on the exposed surface of the n-type GaN layer 2. For comparison with the semiconductor light-emitting device of the first embodiment, another semiconductor light-emitting device (comparative example) is also fabricated which has the same structure as the semiconductor light-emitting device of the first embodiment except that the porous structure 9 is not formed.

The line (a) in FIG. 2 illustrates the current (driving current passed through the p-side ohmic electrode 7)-light power characteristics of the semiconductor light-emitting device of the first embodiment, while the line (b) in FIG. 2 illustrates the current-light power characteristics of the semiconductor light-emitting device with no porous structure, which is formed for comparison. As understood from FIG. 2, by using the porous structure 9 in the present invention, the light power was enhanced by about three times.

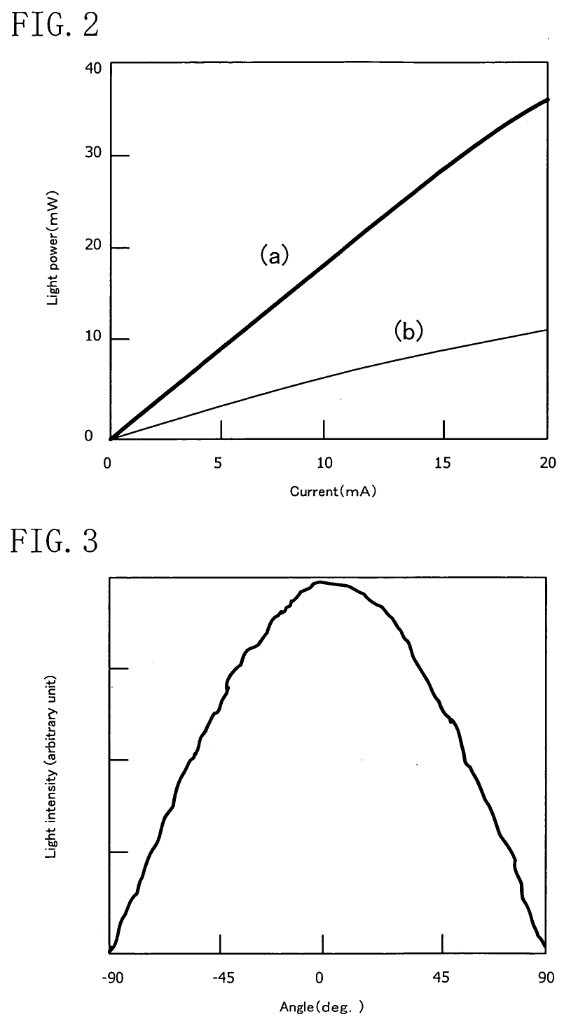

FIG. 3 shows a radiation pattern of light radiated from the semiconductor light-emitting device according to the first embodiment. In FIG. 3, the reference of the angle (0°) showing the direction of light radiation is set in the vertically upward direction of the device (the direction of the normal to the principal surface of the wafer). Referring to FIG. 3, the semiconductor light-emitting device of the first embodiment provides a good radiation pattern without any specific interference peaks.

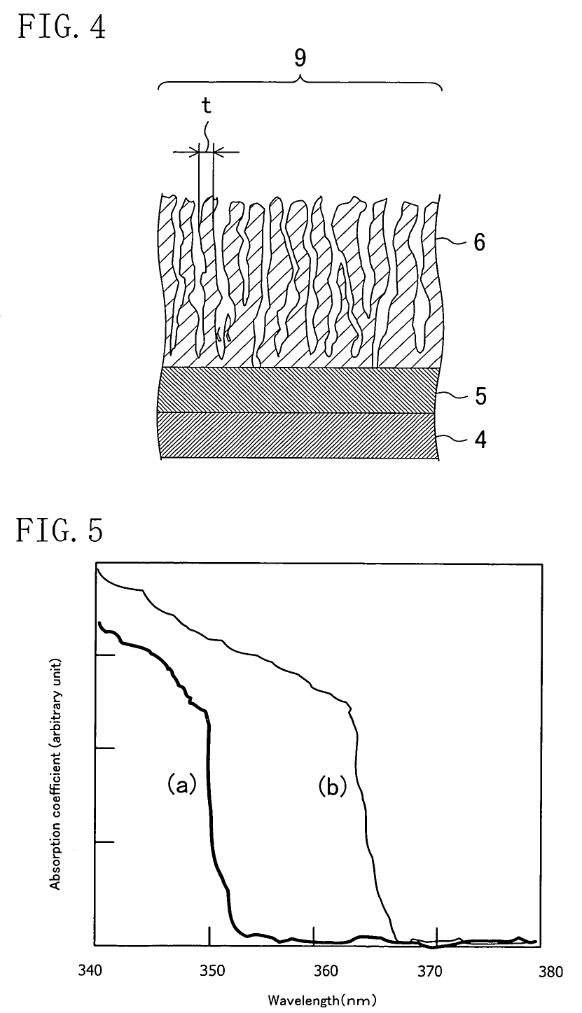

FIG. 4 is a view schematically showing the cross-sectional structure of the porous structure 9 of the p-type GaN contact layer 6 in the semiconductor light-emitting device according to the first embodiment. Referring to FIG. 4, a large number of slender air gaps are formed to extend from the surface side of the p-type GaN contact layer 6 toward the inside of the GaN crystal. In the first embodiment, the reason why the light power is enhanced while a good radiation pattern without any interference peaks is attained is probably that the porous structure 9 with the air gaps randomly formed effectively scatters light. Since the process of making the GaN layer porous proceeds randomly, the plane made by connecting bottoms (in other words, the deepest parts) of the air gaps in the porous structure 9 is not flat and has irregularities with a difference in level of about 10 nm or greater. This unevenness would generate a more effective scattering of light, and thereby improve the light-extraction efficiency. In addition, in order to generate a more effective scattering of light, it is desirable to form irregularities also on the top surface side of the porous structure 9. To be more specific, in the porous structure 9 with a plurality of columnarly-remaining semiconductor portions, the plane made by connecting tops of the remaining semiconductor portions preferably has irregularities with a difference in level of about 10 nm or greater. The above-shown irregularities on the top surface side or the bottom side of the porous structure 9 can be formed by optimizing the condition of porous portion formation process (the composition and content of the mixed solution (wet etching solution), the process temperature, the process time, and the like) or by further utilizing photolithography and etching processes in combination.

In the first embodiment, the p-type AlGaN/GaN strained superlattice layer 5 and the p-type AlGaN electron barrier layer 4 are provided between the InGaN multiple quantum well active layer 3 and the p-type GaN contact layer 6. Thus, it is desirable to form one or more heterointerfaces by providing, between the active layer and the contact layer, semiconductor layers not made porous and serving as current diffusion layers. The reason for this is as follows. From the p-side ohmic electrode 7 with the opening over the light extraction portion of the p-type GaN contact layer 6, that is, from the p-side ohmic electrode 7 formed on the non-porous region of the p-type GaN contact layer 6, carriers are injected. By the presence of the porous structure 9, the carriers injected therefrom hardly diffuse laterally (in the parallel direction with the principal surface of the substrate) in the p-type GaN contact layer, so that provision of uniform light emission from the entire light-extraction surface is likely to be difficult. In contrast to this, like the first embodiment, a plurality of heterointerfaces can be provided between the active layer and the contact layer to promote lateral carrier diffusion, thereby attaining a more uniform light emission.

FIG. 5 shows optical absorption spectra of p-type GaN. In FIG. 5, the curve (a) shows the optical absorption spectrum of p-type GaN in which the porous structure is formed, and the curve (b) shows the optical absorption spectrum of p-type GaN in which the porous structure has not been formed yet. As understood from FIG. 5, the porous structure is formed in the p-type GaN to shift the wavelength of the optical absorption edge (the wavelength at which the absorption coefficient of light sharply falls) of the spectrum to shorter wavelength. In other words, the optical absorption edge of the porous region of the p-type GaN has a shorter wavelength than the optical absorption edge of the non-porous region of the p-type GaN. This probably arises because sufficiently small sizes of the p-type GaN portions remaining in the porous structure cause the quantum effect. To be more specific, such a quantum effect occurs in the case where the average size of the p-type GaN portions in the porous structure 9, which is represented by t in FIG. 4, is about 20 nm or smaller. In other words, the distance between the adjacent air gaps in the porous structure 9 is preferably about 20 nm or smaller. Note that this distance is never smaller than the minimum possible width of the p-type GaN portions in the porous structure 9 (about 0.5 nm which is the thickness of one atom layer).

The shift in the wavelength of the optical absorption edge to shorter wavelength as shown in FIG. 5 is particularly useful in the case where the wavelength of light emitted from the active layer (center wavelength) is almost the same as the wavelength of the forbidden band of the contact layer (about 365 nm for p-type GaN) or shorter than that wavelength. That is to say, by forming the porous structure as described above in the contact layer, the wavelength of the optical absorption edge of the porous structure in the contact layer can be shorter than that of light emitted from the active layer. Thereby, the light emitted from the active layer can be extracted without any absorption into the contact layer, so that the light-extraction efficiency of the device can be further improved.

As described above, in the first embodiment, the p-type GaN contact layer 6 having the surface as the light-extraction surface is formed with the porous structure 9. This prevents light emitted from the InGaN multiple quantum well active layer 3 from being totally reflected at the surface of the p-type GaN contact layer 6, whereby the light-extraction efficiency of the device can be improved. Moreover, the contact layer is made porous to form a great number of air gaps randomly. This avoids a situation where a specific radiation pattern of light radiated from the device is generated by interference between diffracted lights. Consequently, the semiconductor light-emitting device having a high light-extraction efficiency and a good radiation pattern can be provided.

Furthermore, in the first embodiment, the p-type GaN contact layer 6 can be made porous by wet etching. This avoids a problem that dry etching induces damages to the p-type GaN contact layer 6.

Moreover, in the first embodiment, the wavelength of the optical absorption edge of the p-type GaN contact layer 6 made porous shifts to shorter wavelength than that before the contact layer is made porous. This reduces absorption of light emitted from the InGaN multiple quantum well active layer 3, whereby the light-extraction efficiency of the device can be further improved.

Furthermore, in the first embodiment, it is unnecessary to use a sophisticated photolithography technique for fabrication of the device. This enhances the fabrication yield.

In the first embodiment, in order to make the p-type GaN contact layer 6 porous, a mixed solution of methanol, hydrofluoric acid, and hydrogen peroxide solution is used. Instead of this solution, a mixed solution of hydrofluoric acid and hydrogen peroxide solution may be used. If, as the contact layer, a SiC layer is used instead of the p-type GaN layer, a wet etching solution containing HF (hydrogen fluoride) and S₂O₈⁴⁻ may be used to make the SiC layer porous.

In the first embodiment, it is preferable to form a reflection film made of metal or a multilayer dielectric structure on the back surface of the sapphire substrate 1 (the opposite surface to the surface with the n-type GaN layer 2 and other layers formed thereon). Thus, light emitted from the InGaN multiple quantum well active layer 3 toward the sapphire substrate 1 is efficiently reflected by the formed reflection film, so that the efficiency of light extraction from the light-extraction surface can be further improved.

In the first embodiment, the p-type GaN contact layer 6 is formed with the porous structure 9. Alternatively, even if an additional semiconductor layer provided over the p-type GaN contact layer 6 is formed with the porous structure 9, the same effects can be provided for the device.

### MODIFICATION OF FIRST EMBODIMENT

A semiconductor light-emitting device and a method for fabricating the device according to a modification of the first embodiment of the present invention will be described below with reference to the accompanying drawings. This modification differs from the first embodiment in the cross-sectional construction of the porous structure 9 in the p-type GaN contact layer 6. That is to say, the basic construction, other than the porous structure 9, of the semiconductor light-emitting device according to this modification is similar to that of the device according to the first embodiment shown in FIGS. 1A and 1B.

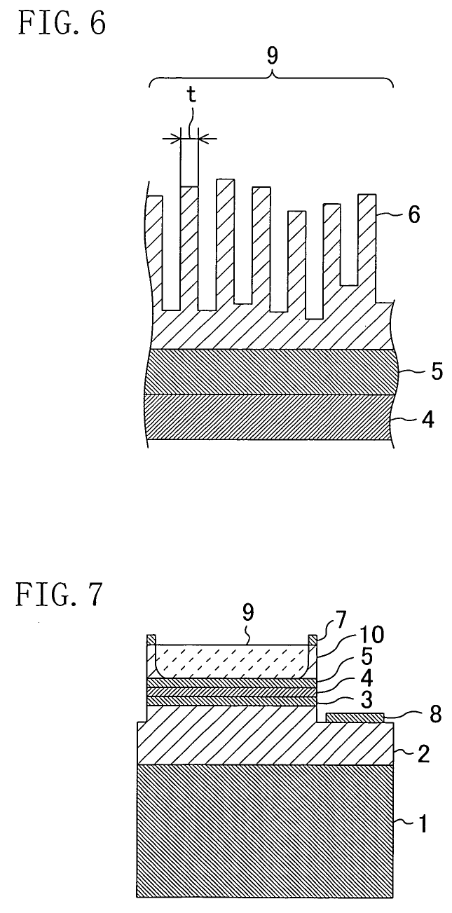

FIG. 6 is a view schematically showing the cross-sectional structure of the porous structure 9 of the p-type GaN contact layer 6 in the semiconductor light-emitting device according to this modification.

The method for fabricating a semiconductor light-emitting device according to this modification is as follows. First, using an MOCVD method or the like, an n-type GaN layer 2 (about 3.0 μm thick), an InGaN multiple quantum well active layer 3, a p-type Al_{0.15}Ga_{0.85}N electron barrier layer 4 (10 nm thick), a p-type AlGaN/GaN strained superlattice layer 5, and a p-type GaN contact layer 6 (50 nm thick) are sequentially stacked on top of a sapphire (0001) substrate 1 of a wafer. In this structure, the InGaN multiple quantum well active layer 3 is formed by laminating three cycles of stacked structures each made of an In_{0.1}Ga_{0.9}N quantum well layer (2.5 nm thick) and an In_{0.02}Ga_{0.98}N barrier layer (5 nm thick). The p-type AlGaN/GaN strained superlattice layer 5 is formed by laminating fifty cycles of stacked structures each made of a p-type Al_{0.1}Ga_{0.9}N layer (1.5 nm thick) and a p-type GaN layer (1.5 nm thick).

In this modification, in order to increase the defect density of the crystal of the p-type GaN contact layer 6, the crystal growth condition for formation of the p-type GaN contact layer 6 is shifted from the crystal growth condition to be typically employed. To be more specific, the temperature for crystal growth of the p-type GaN contact layer 6 is set at 900° C. that is lower than the temperature for typical GaN crystal growth by about 100° C.

Next, a p-side ohmic electrode 7 is formed to have an opening over a light extraction portion of the p-type GaN contact layer 6. Thereafter, the wafer on which the semiconductor layers shown above are stacked is immersed in, for example, a mixed solution of methanol, hydrofluoric acid, and hydrogen peroxide solution, thereby forming a porous structure (a porous region) 9 in the light extraction portion of the p-type GaN contact layer 6 as shown in FIG. 6. Subsequently, of the stacked structure of the semiconductor layers shown above, an n-side ohmic electrode formation region is etched by dry etching to expose the n-type GaN layer 2, and then an n-side ohmic electrode 8 is formed on the exposed surface of the n-type GaN layer 2.

In this modification, as described above, the defect density of the crystal of the p-type GaN contact layer 6 is increased. Thus, in forming the porous region 9, GaN is etched anisotropically with crystal defects in the layer serving as centers of this etching. As a result, the p-type GaN contact layer 6 is etched perpendicularly to the principal surface of the substrate (the (0001) plane). Therefore, as shown in FIG. 6, columnar structures in the porous region 9 which are formed by the etching have side surfaces in parallel with each other. In this modification, respective diameters t of the columnar structures measured in the direction along the (0001) plane average about 40 nm.

Also in this modification, as shown in FIG. 6, a large number of slender air gaps are formed to extend from the surface side of the p-type GaN contact layer 6 toward the inside of the GaN crystal. This provides an effective scattering of light. Therefore, a good radiation pattern without any interference peaks is attained and concurrently the light power of the device can be enhanced. Further, since the process of making the GaN layer porous proceeds randomly, the plane made by connecting bottoms (in other words, the deepest parts) of the air gaps in the porous structure 9 is not flat and has irregularities with a difference in level of about 10 nm or greater. This generates a more effective scattering of light, and thereby improves the light-extraction efficiency. In addition, in order to generate a more effective scattering of light, it is desirable to form irregularities also on the top surface side of the porous structure 9. To be more specific, in the porous structure 9 with a plurality of columnarly-remaining semiconductor portions, the plane made by connecting tops of the remaining semiconductor portions preferably has irregularities with a difference in level of about 10 nm or greater. The above-shown irregularities on the top surface side or the bottom side of the porous structure 9 can be formed by optimizing the condition of porous portion formation process (the composition and content of the mixed solution (wet etching solution), the process temperature, the process time, and the like) or by further utilizing photolithography and etching processes in combination.

Also in this modification, the p-type AlGaN/GaN strained superlattice layer 5 and the p-type AlGaN electron barrier layer 4 are provided between the InGaN multiple quantum well active layer 3 and the p-type GaN contact layer 6. Thus, it is desirable to form one or more heterointerfaces by providing, between the active layer and the contact layer, semiconductor layers not made porous and serving as current diffusion layers. The reason for this is as follows. From the p-side ohmic electrode 7 with the opening over the light extraction portion of the p-type GaN contact layer 6, that is, from the p-side ohmic electrode 7 formed on the non-porous region of the p-type GaN contact layer 6, carriers are injected. By the presence of the porous structure 9, the carriers injected therefrom hardly diffuse laterally (in the parallel direction with the principal surface of the substrate) in the p-type GaN contact layer, so that provision of uniform light emission from the entire light-extraction surface is likely to be difficult. In contrast to this, like this modification, a plurality of heterointerfaces can be provided between the active layer and the contact layer to promote lateral carrier diffusion, thereby attaining a more uniform light emission.

As described above, in this modification, the p-type GaN contact layer 6 having the surface as the light-extraction surface is formed with the porous structure 9. This prevents light emitted from the InGaN multiple quantum well active layer 3 from being totally reflected at the surface of the p-type GaN contact layer 6, whereby the light-extraction efficiency of the device can be improved. Moreover, the contact layer is made porous to form a great number of air gaps randomly. This avoids a situation where a specific radiation pattern of light radiated from the device is generated by interference between diffracted lights. Consequently, the semiconductor light-emitting device having a high light-extraction efficiency and a good radiation pattern can be provided.

Furthermore, in this modification, the p-type GaN contact layer 6 can be made porous by wet etching. This avoids a problem that dry etching induces damages to the p-type GaN contact layer 6.

Moreover, in this modification, the wavelength of the optical absorption edge of the p-type GaN contact layer 6 made porous shifts to shorter wavelength than that before the contact layer is made porous. This reduces absorption of light emitted from the InGaN multiple quantum well active layer 3, whereby the light-extraction efficiency of the device can be further improved.

Furthermore, in this modification, it is unnecessary to use a sophisticated photolithography technique for fabrication of the device. This enhances the fabrication yield.

In this modification, in order to make the p-type GaN contact layer 6 porous, a mixed solution of methanol, hydrofluoric acid, and hydrogen peroxide solution is used. Instead of this solution, a mixed solution of hydrofluoric acid and hydrogen peroxide solution may be used. If, as the contact layer, a SiC layer is used instead of the p-type GaN layer, a wet etching solution containing HF (hydrogen fluoride) and S₂O₈⁴⁻ may be used to make the SiC layer porous.

In this modification, it is preferable to form a reflection film made of metal or a multilayer dielectric structure on the back surface of the sapphire substrate 1 (the opposite surface to the surface with the n-type GaN layer 2 and other layers formed thereon). Thus, light emitted from the InGaN multiple quantum well active layer 3 toward the sapphire substrate 1 is efficiently reflected by the formed reflection film, so that the efficiency of light extraction from the light-extraction surface can be further improved.

In this modification, the p-type GaN contact layer 6 is formed with the porous structure 9. Alternatively, even if an additional semiconductor layer provided over the p-type GaN contact layer 6 is formed with the porous structure 9, the same effects can be provided for the device.

### SECOND EMBODIMENT

A semiconductor light-emitting device and a method for fabricating the device according to a second embodiment of the present invention will be described below with reference to the accompanying drawings.

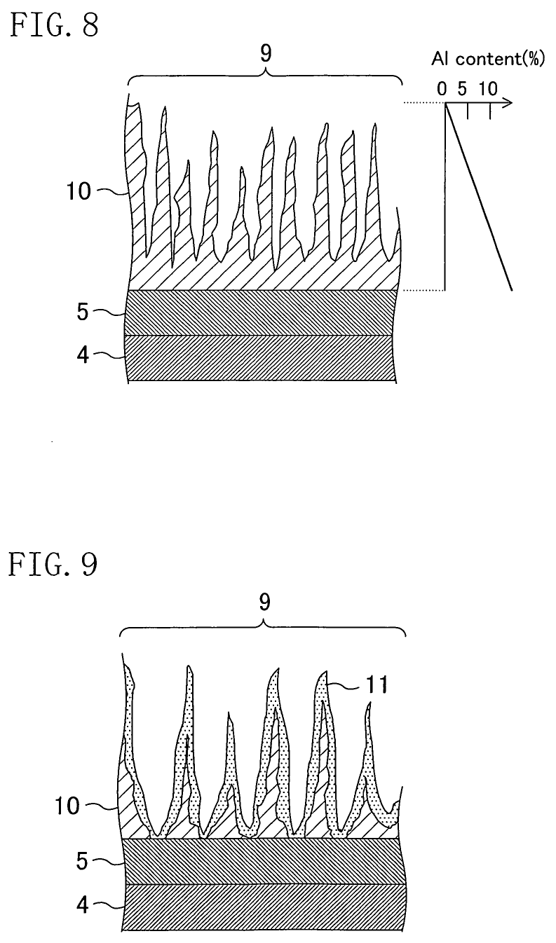

FIG. 7 is a view showing the cross-sectional structure of the semiconductor light-emitting device according to the second embodiment. The semiconductor light-emitting device according to the second embodiment differs from the device according to the first embodiment (see FIGS. 1A and 1B) in that as shown in FIG. 7, not the p-type GaN contact layer 6 but a p-type AlGaN contact layer 10 with a gradient composition is formed of which the Al content continuously decreases, for example, from about 10 to 0% from the substrate side toward the surface side. All components other than that are identical to those in the first embodiment including the fabrication method thereof FIG. 8 is a view schematically showing the cross-sectional structure of a porous structure 9 of the p-type AlGaN contact layer 10 with a gradient composition included in the semiconductor light-emitting device of the second embodiment. Note that FIG. 8 shows a graph illustrating a change in the Al content of the AlGaN contact layer 10 with a gradient composition in combination with the view of the cross-sectional structure shown above.

Referring to FIG. 8, in the porous structure 9 in the second embodiment, the dimensions (widths) of respective p-type AlGaN portions gradually decrease from the substrate side toward the surface side. This is because the etching rate of AlGaN (the etching rate during the porous portion formation process like the first embodiment) increases as the Al content is lowered. Therefore, in the porous structure 9, the packing density of the p-type AlGaN gradually decreases from the substrate side toward the surface side. In other words, the ratio of air gaps per unit volume of the porous structure 9 rises as the distance from the InGaN multiple quantum well active layer 3 is increased. As a consequence of this, the effective refractive index of the porous structure 9 of the p-type AlGaN contact layer 10 with a gradient composition gradually decreases from the substrate side toward the surface side, so that the light-extraction efficiency of the device can be improved more than that of the first embodiment.

In the second embodiment, the Al content of the p-type AlGaN contact layer 10 with a gradient composition is continuously changed. Instead of this, the Al content thereof may be changed stepwise. As an alternative to the p-type AlGaN contact layer 10 with a gradient composition, another layer with a gradient composition may be used which has a band gap energy stepwise or continuously decreasing with increasing distance from the InGaN multiple quantum well active layer 3. Even in such a case, the ratio of air gaps per unit volume of the porous region in another said layer with a gradient composition can be raised as the distance from the active layer is increased, whereby the effective refractive index of the porous region of another said layer with a gradient composition gradually decreases from the substrate side toward the surface side. Consequently, the light-extraction efficiency of the device can be improved more.

### THIRD EMBODIMENT

A semiconductor light-emitting device and a method for fabricating the device according to a third embodiment of the present invention will be described below with reference to the accompanying drawings. The semiconductor light-emitting device according to the third embodiment differs from the device according to the second embodiment (see FIGS. 7 and 8) in the detail construction of a porous structure 9 in a p-type AlGaN contact layer 10 with a gradient composition. That is to say, the device structure in the third embodiment other than this detail construction is identical to that in the second embodiment.

FIG. 9 is a view schematically showing the cross-sectional structure of the porous structure 9 of the p-type AlGaN contact layer 10 with a gradient composition included in the semiconductor light-emitting device according to the third embodiment.

Referring to FIG. 9, in the third embodiment, on the semiconductor surface of the p-type AlGaN contact layer 10 with a gradient composition in contact with air gaps of the porous structure 9, an oxide film 11 (specifically Ga₂Oₓ (0≦x≦3)) is formed by thermal oxidation. This film prevents the AlGaN surface in the porous structure 9 from being directly exposed to an atmosphere, so that the reliability of the device is improved more greatly than the second embodiment.

In the third embodiment, description has been made of the case as an example where in the p-type AlGaN contact layer 10 with a gradient composition formed with the porous structure 9, the AlGaN surface is oxidized. However, this embodiment is not limited to this case. Alternatively, even if the contact layer is made of GaN, AlGaInN, InGaN, or the like and a semiconductor surface of the porous structure thereof is oxidized, the same effects can be provided for the device.

### FOURTH EMBODIMENT

A semiconductor light-emitting device and a method for fabricating the device according to a fourth embodiment of the present invention will be described below with reference to the accompanying drawings. The semiconductor light-emitting device according to the fourth embodiment differs from the device according to the first embodiment (see FIGS. 1A and 1B and FIG. 4) in the detail construction of a porous structure 9 in a p-type GaN contact layer 6. That is to say, the device structure in the fourth embodiment other than this detail construction is identical to that in the first embodiment.

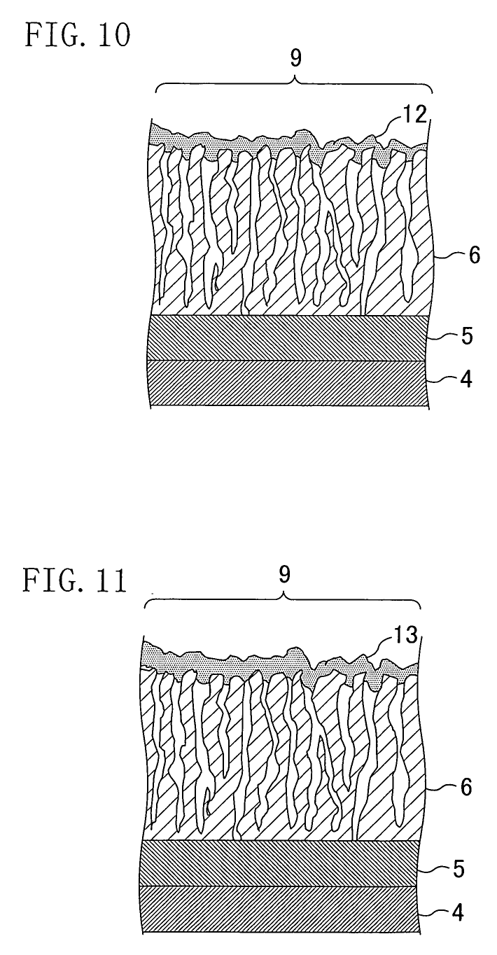

FIG. 10 is a view schematically showing the cross-sectional structure of the porous structure 9 of the p-type GaN contact layer 6 included in the semiconductor light-emitting device of the fourth embodiment.

Referring to FIG. 10, in the fourth embodiment, the porous structure 9 of the p-type GaN contact layer 6 is covered with a protection film 12 formed by CVD (chemical vapor deposition) technique, sputtering technique, or the like. In this case, as shown in FIG. 10, the protection film 12 is not formed to reach the inside of the porous structure 9. That is to say, the protection film 12 is formed only around the surface of the porous structure 9. However, this structure prevents the GaN surface in the porous structure 9 from being directly exposed to an atmosphere, so that the reliability of the device is improved more greatly than that of the first embodiment.

In the fourth embodiment, the protection film 12 is not limited to any particular material, and may be made of a single-layer structure or a multilayer structure made of a material or materials selected from, for example, SiO₂, Al₂O₃, SiN, TiO₂, ZrO₂, Nb₂O₅, Ta₂O₅, or Ga₂O₃.

### FIFTH EMBODIMENT

A semiconductor light-emitting device and a method for fabricating the device according to a fifth embodiment of the present invention will be described below with reference to the accompanying drawings. The semiconductor light-emitting device according to the fifth embodiment differs from the device according to the first embodiment (see FIGS. 1A and 1B and FIG. 4) in the detail construction of a porous structure 9 of a p-type GaN contact layer 6. That is to say, the device structure in the fifth embodiment other than this detail construction is identical to that in the first embodiment.

FIG. 11 is a view schematically showing the cross-sectional structure of the porous structure 9 of the p-type GaN contact layer 6 included in the semiconductor light-emitting device according to the fifth embodiment.

Referring to FIG. 11, in the fifth embodiment, the porous structure 9 of the p-type GaN contact layer 6 is covered with a transparent conductive film (transparent electrode) 13. This structure prevents the GaN surface in the porous structure 9 from being directly exposed to an atmosphere, so that the reliability of the device is improved more greatly than that of the first embodiment. In addition, a more uniform carrier injection from the p-side ohmic electrode 7 (see FIGS. 1A and 1B) can be performed, so that the efficiency of light emission of the device can be still further improved.

In the fifth embodiment, the transparent conductive film 13 is not limited to any particular material, and can be made of, for example, ITO (In₂SnO₃) or β-GaO₃. As the transparent conductive film 13, use may be made of a stacked film of a Ni film and a Au film both of which have reduced thicknesses of several nanometers or smaller.

### SIXTH EMBODIMENT

A semiconductor light-emitting device and a method for fabricating the device according to a sixth embodiment of the present invention will be described below with reference to the accompanying drawings.

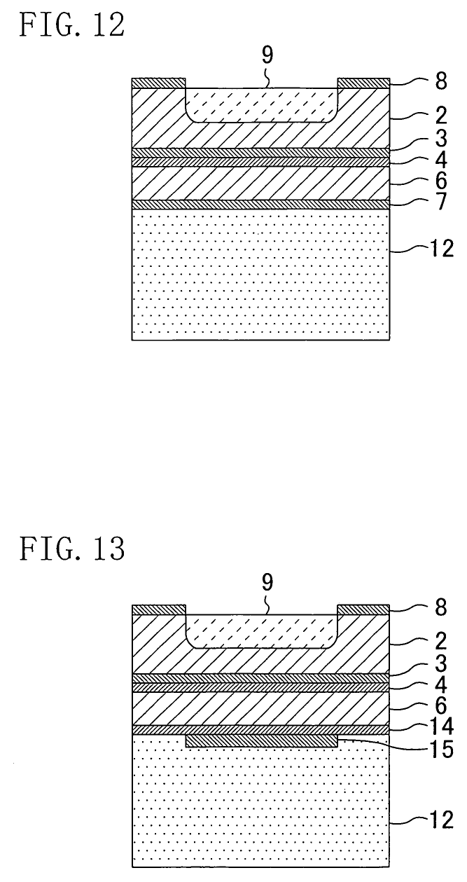

FIG. 12 is a view showing the cross-sectional structure of the semiconductor light-emitting device according to the sixth embodiment.

The method for fabricating a semiconductor light-emitting device according to the sixth embodiment is as follows. Similarly to the first embodiment, first, using an MOCVD method or the like, an n-type GaN layer 2 (about 3.0 μm thick), an InGaN multiple quantum well active layer 3, a p-type Al_{0.15}Ga_{0.85}N electron barrier layer 4 (10 nm thick), and a p-type GaN contact layer 6 (50 nm thick) are sequentially stacked on top of a sapphire substrate (not shown) of a wafer. In this structure, the InGaN multiple quantum well active layer 3 is formed by laminating three cycles of stacked structures each made of an In_{0.1}Ga_{0.9}N quantum well layer (2.5 nm thick) and an In_{0.02}Ga_{0.98}N barrier layer (5 nm thick).

Next, a p-side ohmic electrode 7 and a Au plating layer 12 are sequentially stacked over the entire surface of the p-type GaN contact layer 6. Thereafter, for example, a short-pulse ultraviolet laser light is radiated from the sapphire substrate side to exfoliate the sapphire substrate from the crystal growth layer (the stacked structure of the semiconductor layers shown above). Subsequently, an n-side ohmic electrode 8 is formed to have an opening over the surface of the light extraction portion included in the surface of the n-type GaN layer 2 exposed by the substrate exfoliation. Finally, a portion of the n-type GaN layer 2 exposed in the opening of the n-side ohmic electrode 8 is made porous to form a porous structure (porous region) 9. Note that FIG. 12 shows the cross-sectional structure of the device in which after the substrate exfoliation, the side of the n-type GaN layer 2 is positioned upward and the side of the p-type GaN contact layer 6 is positioned downward.

As described above, in the sixth embodiment, the porous structure 9 is formed in the n-type GaN layer 2 having the surface serving as the light-extraction surface. This prevents light emitted from the InGaN multiple quantum well active layer 3 from being totally reflected at the surface of the n-type GaN layer 2, whereby the light-extraction efficiency of the device can be improved. Moreover, part of the n-type GaN layer 2 is made porous to form a great number of air gaps randomly. This avoids a situation where a specific radiation pattern of light radiated from the device is generated by interference between diffracted lights. Consequently, the semiconductor light-emitting device having a high light-extraction efficiency and a good radiation pattern can be provided.

Furthermore, in the sixth embodiment, the n-type GaN layer 2 can be made porous by wet etching. This avoids a problem that dry etching induces damages to the n-type GaN layer 2.

Moreover, in the sixth embodiment, the wavelength of the optical absorption edge of the n-type GaN layer 2 made porous shifts to shorter wavelength than that before the n-type GaN layer is made porous. This reduces absorption of light emitted from the InGaN multiple quantum well active layer 3, whereby the light-extraction efficiency of the device can be further improved.

Furthermore, in the sixth embodiment, it is unnecessary to use a sophisticated photolithography technique for fabrication of the device. This enhances the fabrication yield.

Moreover, in the sixth embodiment, the p-side ohmic electrode 7 generally having a higher contact resistance than the n-side electrode can be formed, without providing an opening, on the entire surface of the p-type GaN contact layer 6. This reduces the operating voltage of the device. To be more specific, for example, the operating voltage when the device is driven at 20 mA can be decreased from 3.0 V to 2.8 V.

Furthermore, in the sixth embodiment, a material with a high reflectivity with respect to the wavelength of light emitted from the InGaN multiple quantum well active layer 3, such as Pt, Rh, or Ag, can be used as the material for the p-type ohmic electrode 7 to efficiently reflect, toward the n-type GaN layer 2, light emitted from the InGaN multiple quantum well active layer 3 toward the Au plating layer 12. This further improves the light-extraction efficiency of the device.

In the sixth embodiment, like the first embodiment, the p-type AlGaN/GaN strained superlattice layer may be provided between the p-type AlGaN electron barrier layer 4 and the p-type GaN contact layer 6. In this case, as the p-type AlGaN/GaN strained superlattice layer, use can be made of, for example, a layer formed by laminating fifty cycles of stacked structures each made of a p-type Al_{0.1}Ga_{0.9}N layer (1.5 nm thick) and a p-type GaN layer (1.5 nm thick).

### SEVENTH EMBODIMENT

A semiconductor light-emitting device and a method for fabricating the device according to a seventh embodiment of the present invention will be described below with reference to the accompanying drawings.

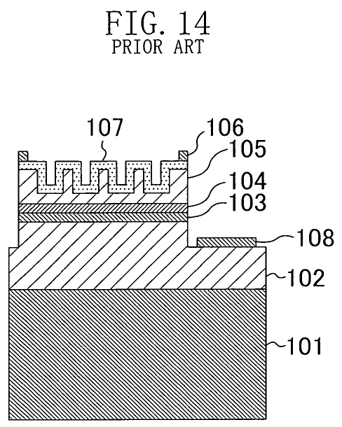

FIG. 13 is a view showing the cross-sectional structure of the semiconductor light-emitting device according to the seventh embodiment.

The method for fabricating a semiconductor light-emitting device according to the seventh embodiment is as follows. Similarly to the sixth embodiment, first, using an MOCVD method or the like, an n-type GaN layer 2 (about 3.0 μm thick), an InGaN multiple quantum well active layer 3, a p-type Al_{0.15}Ga_{0.85}N electron barrier layer 4 (10 nm thick), and a p-type GaN contact layer 6 (50 nm thick) are sequentially stacked on a sapphire substrate (not shown) of a wafer. In this structure, the InGaN multiple quantum well active layer 3 is formed by laminating three cycles of stacked structures each made of an In_{0.1}Ga_{0.9}N quantum well layer (2.5 nm thick) and an In_{0.02}Ga_{0.98}N barrier layer (5.0 nm thick).

Next, a transparent electrode 14 of ITO or the like and a multilayer dielectric structure 15 are formed on the entire surface of the p-type GaN contact layer 6, and all portions of the multilayer dielectric structure 15 other than the region located directly below the light extraction portion of the n-type GaN layer 2 are removed by photolithography and etching. In this structure, the multilayer dielectric structure 15 is formed by alternately depositing, for example, a SiO₂ film (69 nm thick) and a TiO₂ film (40 nm thick) ten times. Thereafter, a Au plating layer 12 is formed on the multilayer dielectric structure 15 and the transparent electrode 14, and then, for example, a short-pulse ultraviolet laser light is radiated from the sapphire substrate side to exfoliate the sapphire substrate from the crystal growth layer (the stacked structure of the semiconductor layers shown above). Subsequently, an n-side ohmic electrode 8 is formed to have an opening over the surface of the light extraction portion included in the surface of the n-type GaN layer 2 exposed by the substrate exfoliation. Finally, a portion of the n-type GaN layer 2 exposed in the opening of the n-side ohmic electrode 8 is made porous to form a porous structure (porous region) 9. Note that FIG. 13 shows the cross-sectional structure of the device in which after the substrate exfoliation, the side of the n-type GaN layer 2 is positioned upward and the side of the p-type GaN contact layer 6 is positioned downward.

With the seventh embodiment, not only the effects similar to the sixth embodiment but also the following effects can be provided. Since light emitted from the InGaN multiple quantum well active layer 3 toward the p-type GaN contact layer 6, that is, toward the Au plating layer 12 is efficiently reflected by the multilayer dielectric structure 15, the efficiency of light extraction from the light-extraction surface (the surface of the n-type GaN layer 2) can be further improved.

In the seventh embodiment, the ten cycles of stacked structures each made of SiO₂ and TiO₂ are used as the multilayer dielectric structure 15. However, the multilayer dielectric structure 15 is not limited to this, and the material, thickness, and the like of the multilayer dielectric structure 15 can be set freely to obtain a high reflectivity with respect to the wavelength of light emitted from the InGaN multiple quantum well active layer 3.

In the seventh embodiment, the reflection film made of the multilayer dielectric structure 15 is formed over the surface of the p-type GaN contact layer 6, which is an opposite surface to the light-extraction surface. Instead of this film, a reflection film of metal may be formed.

In the seventh embodiment, like the first embodiment, a p-type AlGaN/GaN strained superlattice layer may be provided between the p-type AlGaN electron barrier layer 4 and the p-type GaN contact layer 6. In this case, as the p-type AlGaN/GaN strained superlattice layer, use can be made of, for example, a layer formed by laminating fifty cycles of stacked structures each made of a p-type Al_{0.1}Ga_{0.9}N layer (1.5 nm thick) and a p-type GaN layer (1.5 nm thick).

In the seventh embodiment, ITO is used as the material for the transparent electrode 14. Alternatively, for example, β-GaO₃ may be used. As the transparent electrode 14, use may be made of a stacked film of a Ni film and a Au film both of which have reduced thicknesses of several nanometers or smaller, such as a stacked film of a 2-nm thick Ni film and a 3-nm thick Au film.

In the first to seventh embodiments described above, the InGaN multiple quantum well active layer 3 is used as the active layer, and the GaN contact layer 6 or the AlGaN contact layer 10 with a gradient composition is used as the layer with the porous structure formed therein. However, the present invention is not limited to these layers. To be more specific, in the case where a nitride-based compound semiconductor is used as the materials for the semiconductor layers constituting the semiconductor light-emitting device according to the embodiments of the present invention, even if, for example, a material represented by the general formula: BₓAl_{y}In_{z}Ga_{1-x-y-z}N (0≦x≦1, 0≦y≦, 0≦z≦1, 0≦x+y+z≦1) is used for the respective semiconductor layers, the same effects exerted by the embodiments of the present invention can be provided. In such a case, a nitride-based compound semiconductor represented by the general formula: AlₓGa₁₋ₓN (0≦x≦1) may be used as the material for the active layer.

In the first to seventh embodiments, if the wavelength of light emitted from the InGaN multiple quantum well active layer 3 (center wavelength) is 200 nm or greater and smaller than 430 nm, a white color LED can be fabricated.

1. A semiconductor light-emitting device which is formed by stacking a plurality of semiconductor layers including an active layer,
wherein at least a portion of a semiconductor layer of the plurality of semiconductor layers is made porous, the semiconductor layer having a surface serving as a light-extraction surface for extracting light emitted from the active layer.

2. The device of claim 1,
wherein air gaps in the porous region of the semiconductor layer have irregularities in their bottom levels.

3. The device of claim 1,
wherein the porous region of the semiconductor layer has a plurality of remaining semiconductor portions whose tops form irregularities as a whole.

4. The device of claim 1,
wherein the plurality of semiconductor layers include another semiconductor layer not made porous, provided between the active layer and the semiconductor layer, and serving as a current diffusion layer, and
an electrode is provided on a non-porous region of the semiconductor layer.

5. The device of claim 4,
wherein the current diffusion layer has at least one heterointerface.

6. The device of claim 1,
wherein an optical absorption edge of the porous region of the semiconductor layer has a shorter wavelength than that of the non-porous region of the semiconductor layer.

7. The device of claim 1,
wherein the wavelength of the optical absorption edge of the porous region of the semiconductor layer is shorter than the center wavelength of light emitted from the active layer.

8. The device of claim 1,
wherein the distance between adjacent ones of the air gaps in the porous region of the semiconductor layer is 20 nm or smaller.

9. The device of claim 1,
wherein the effective refractive index of the porous region of the semiconductor layer decreases as the distance from the active layer is increased.

10. The device of claim 1,
wherein the ratio of air gaps per unit volume of the porous region of the semiconductor layer rises as the distance from the active layer is increased.

11. The device of claim 1,
wherein the band gap energy of the semiconductor layer stepwise or continuously decreases as the distance from the active layer is increased.

12. The device of claim 1,
wherein portions of the semiconductor surface contacting with the air gaps in the porous region of the semiconductor layer are oxidized.

13. The device of claim 1,
wherein the surface side of the porous region of the semiconductor layer is covered with a protection film.

14. The device of claim 13,
wherein the protection film is made of SiO₂, Al₂O₃, SiN, TiO₂, ZrO₂, Nb₂O₅, Ta₂O₅, or Ga₂O₃.

15. The device of claim 1,
wherein the surface side of the porous region of the semiconductor layer is covered with a transparent electrode.

16. The device of claim 1,
wherein the semiconductor layer is an n-type semiconductor layer.

17. The device of claim 1,
wherein the plurality of semiconductor layers are formed on a substrate, and
a reflection film made of metal or a multilayer dielectric structure is formed on one of principal surfaces of the substrate on which the plurality of semiconductor layers are not formed.

18. The device of claim 1,
wherein a reflection film made of metal or a multilayer dielectric structure is formed on a surface of a still another semiconductor layer of the plurality of semiconductor layers, the surface of the still another semiconductor layer being the opposite surface to the light-extraction surface.

19. The device of claim 1,
wherein each of the plurality of semiconductor layers is made of nitride-based compound semiconductor represented by BₓAl_{y}In_{z}Ga_{1-x-y-z}N (0≦x≦1, 0≦y≦1, 0≦z≦1, 0≦x+y+≦1).

20. The device of claim 19,
wherein the wavelength of light emitted from the active layer is less than 430 nm.

21. The device of claim 1,
wherein the semiconductor layer is made of nitride-based compound semiconductor represented by AlₓGa₁₋ₓN (0≦x≦1).

22. A method for fabricating a semiconductor light-emitting device, comprising the steps of:
sequentially forming, on a substrate, at least an n-type semiconductor layer, a semiconductor layer serving as an active layer, and a p-type semiconductor layer;
separating a multilayer structure including the semiconductor layers from the substrate; and
making at least a portion of the n-type semiconductor layer of the multilayer structure porous, the n-type semiconductor layer having a surface serving as a light-extraction surface for extracting light emitted from the active layer.
